(19) United States
(12) Patent Application Publication
(10) Pub. No.: US 2025/0372397 A1
(43) Pub. Date: Dec. 4, 2025

(54) METHOD FOR PLANARIZING SURFACE OF SEMICONDUCTOR DEVICE

(71) Applicant: UNITED MICROELECTRONICS CORP., Hsin-Chu City (TW)

(72) Inventors: Ching-Hua Hsu, Kaohsiung City (TW); Hui-Lin Wang, Taipei City (TW); Chen-Yi Weng, New Taipei City (TW); Che-Wei Chang, Taichung City (TW); Rai-Min Huang, Taipei City (TW); Po-Kai Hsu, Tainan City (TW)

(73) Assignee: UNITED MICROELECTRONICS CORP., Hsin-Chu City (TW)

(21) Appl. No.: 18/755,712

(22) Filed: Jun. 27, 2024

(30) Foreign Application Priority Data
May 28, 2024 (TW) 113119688

(51) Int. Cl. H01L 21/321; H01L 21/033; H01L 21/3105

(52) U.S. Cl. CPC H01L 21/3212; H01L 21/0337; H01L 21/31056

(57) ABSTRACT

A method for planarizing a surface of a semiconductor device includes steps as follows. A substrate defining a memory region is provided. A memory component is disposed on the substrate and located in the memory region. A dielectric layer is formed to cover the memory component. The dielectric layer includes a protruding portion corresponding to the memory component. A portion of the protruding portion is etched to form a sidewall structure. The sidewall structure includes an etched side surface, and an included angle between the etched side surface of the sidewall structure and an etched top surface of the protruding portion is an obtuse angle. The sidewall structure is removed to planarize the dielectric layer.

### BACKGROUND OF THE INVENTION

### 1. Field of the Invention

The present disclosure relates to the field of semiconductor devices, and more particularly, to a method for planarizing a surface of a semiconductor device.

### 2. Description of the Prior Art

In the manufacturing process of semiconductor devices, it is often necessary to planarize surfaces of the semiconductor devices. When there are defects generated on one of the layers of the semiconductor devices, properties of the next layer will be affected.

Taking the semiconductor device including a magnetoresistive random-access memory (MRAM) as an example, in part of the manufacturing process of the semiconductor device including the MRAM, the MRAM protrudes from the semiconductor device. In the subsequent process of planarizing the dielectric layer covering the MRAM, if the surface of the dielectric layer is accidentally damaged, for example, dents or scratches are formed on the surface of the dielectric layer, it is easy to cause the metal material to fill in the aforementioned dents or scratches during the subsequent metal interconnection process, which may generate bridges between different metal wires and cause short circuits. Accordingly, the performance and/or yield of the semiconductor devices formed later are affected. Therefore, how to improve the method for planarizing the surfaces of the semiconductor devices has become the goal of relevant industries.

### SUMMARY OF THE INVENTION

According to one aspect of the present disclosure, a method for planarizing a surface of a semiconductor device includes steps as follows. A substrate defining a memory region is provided, in which a memory component is disposed on the substrate and located in the memory region. A dielectric layer is formed to cover the memory component, in which the dielectric layer includes a protruding portion corresponding to the memory component. A portion of the protruding portion is etched to form a sidewall structure, in which the sidewall structure includes an etched side surface, and an included angle between the etched side surface of the sidewall structure and an etched top surface of the protruding portion is an obtuse angle. The sidewall structure is removed to planarize the dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1, FIG. 2, FIG. 3, FIG. 4, FIG. 5, FIG. 6, FIG. 7 and FIG. 8 are schematic cross-sectional views showing steps of a method for planarizing a surface of a semiconductor device according to an embodiment of the present disclosure.

FIG. 9 is a schematic cross-sectional view showing a step of a method for planarizing a surface of a semiconductor device according to another embodiment of the present disclosure.

### DETAILED DESCRIPTION

In the following detailed description of the embodiments, reference is made to the accompanying drawings which form a part thereof, and in which is shown by way of illustration specific embodiments in which the disclosure may be practiced. In this regard, directional terminology, such as up, down, left, right, front, back, bottom or top is used with reference to the orientation of the Figure(s) being described. The elements of the present disclosure can be positioned in a number of different orientations. As such, the directional terminology is used for purposes of illustration and is in no way limiting. In addition, identical numeral references or similar numeral references are used for identical elements or similar elements in the following embodiments.

Hereinafter, for the description of “the first feature is formed on or above the second feature”, it may refer that “the first feature is in contact with the second feature directly”, or it may refer that “there is another feature between the first feature and the second feature”, such that the first feature is not in contact with the second feature directly.

It is understood that, although the terms first, second, etc. may be used herein to describe various elements, regions, layers and/or sections, these elements, regions, layers and/or sections should not be limited by these terms. These terms may be only used to distinguish one element, region, layer and/or section from another element, region, layer and/or section. Terms such as “first,” “second,” and other numerical terms when used herein do not imply a sequence or order unless clearly indicated by the context. Thus, a first element, region, layer and/or section discussed below could be termed a second element, region, layer and/or section without departing from the teachings of the embodiments. The terms used in the claims may not be identical with the terms used in the specification, but may be used according to the order of the elements claimed in the claims.

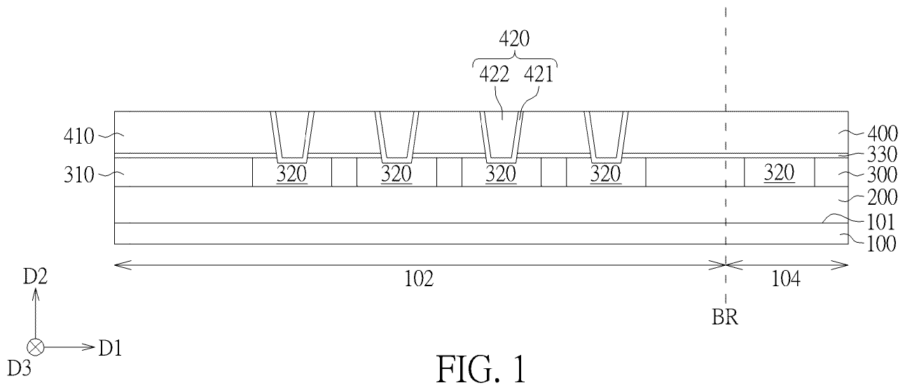

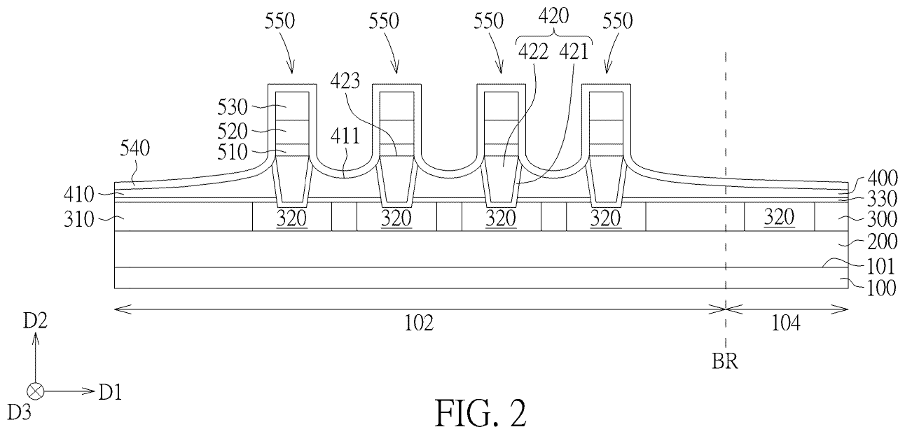

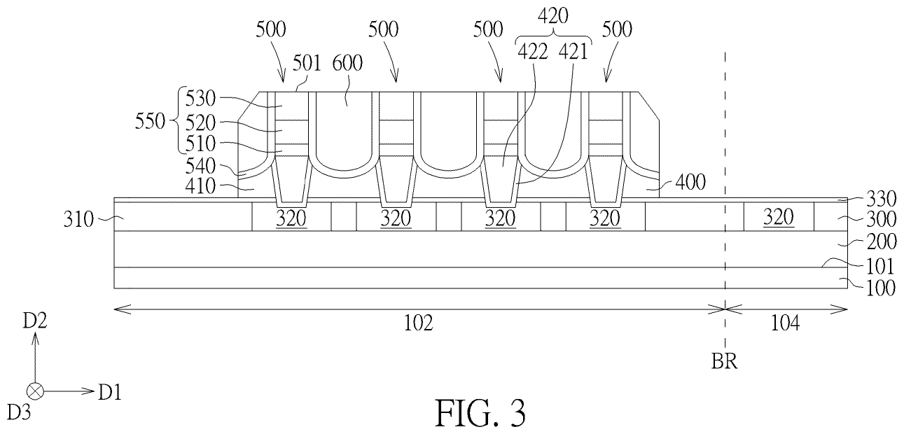

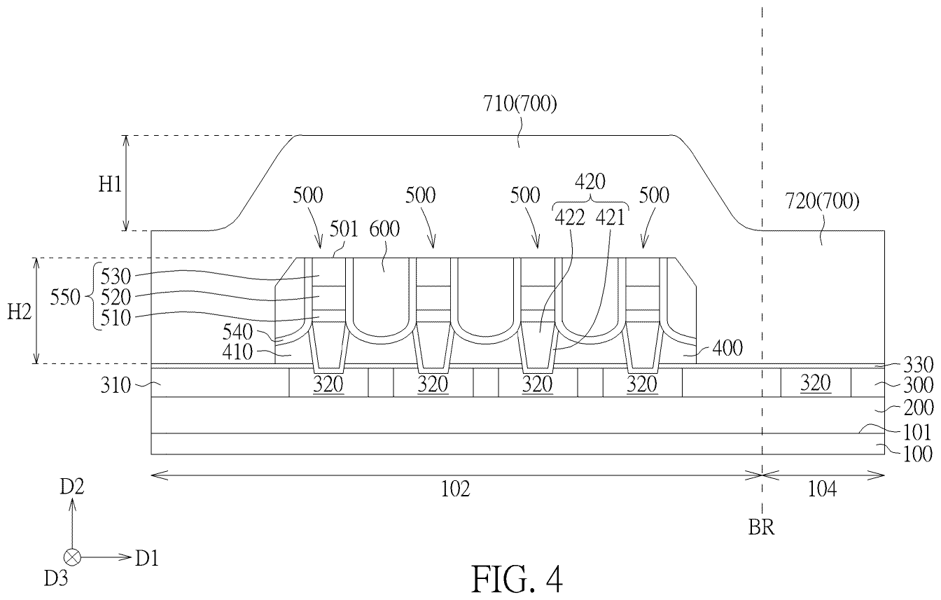

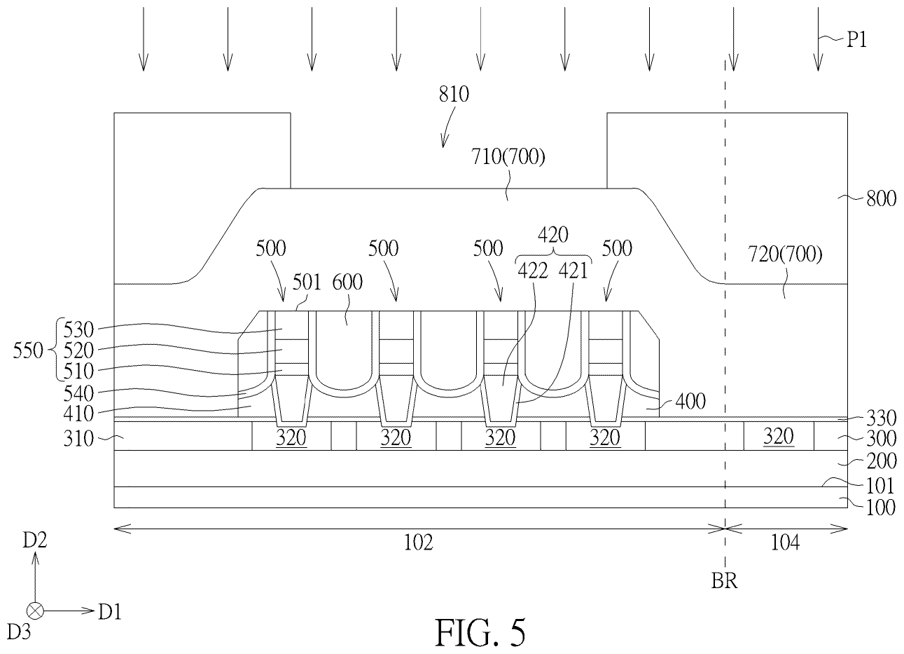

Please refer to FIG. 1 to FIG. 8, which are schematic cross-sectional views showing steps of a method for planarizing a surface of a semiconductor device according to an embodiment of the present disclosure. In FIG. 1, a substrate 100 is provided. The substrate 100 may be a silicon substrate, an epitaxial silicon substrate, a silicon carbide substrate or a silicon on insulator (SOI) substrate. The substrate 100 may define a memory region 102 and at least one region 104 adjacent to the memory region 102. The memory region 102 has a boundary BR located between the memory region 102 and the region 104. The memory region 102 is configured for disposing a memory component, such as the memory component 500 (see FIG. 3) formed later. The memory component 500 may be, for example, a MRAM cell or a resistive random-access memory (RRAM) cell. According to an embodiment of the present disclosure, the memory component 500 may be a magnetic tunnel junction (MTJ) component. The region 104 may be a logic region or a peripheral region, but not limited thereto.

The substrate 100 may include, for example, semiconductor components (not shown) disposed thereon and a dielectric layer 200 covering the aforementioned semiconductor components. The aforementioned semiconductor components may include various active components or passive components, such as a planar or non-planar metal-oxide semiconductor (MOS) transistor, diodes, capacitors, inductors, and resistors, but not limited thereto. In the dielectric layer 200, a plurality of contact plugs (not shown) may be disposed to be electrically connected with the gate (not shown) and/or the source/drain regions (not shown) of the MOS transistor.

Next, a metal interconnect process may be performed to form a metal interconnect structure 300 on the dielectric layer 200 to be electrically connected with the aforementioned contact plugs. The metal interconnect structure 300 includes an inter-metal dielectric layer 310 and wires 320 embedded in the inter-metal dielectric layer 310. The wire 320 may include, for example, a trench conductor, and a material of the wire 320 may include a metal material, such as aluminum (Al), titanium (Ti), tantalum (Ta), tungsten (W), niobium (Nb), molybdenum (Mo), copper (Cu) or a combination thereof, but not limited thereto. According to an embodiment of the present disclosure, the material of the wire 320 includes copper. Herein, the wire 320 is exemplary a single-layer structure. In other embodiment, the wire 320 may be a multi-layer structure. For example, the wire 320 may further include a barrier layer (not shown), and a material of the barrier layer may include titanium (Ti), tantalum (Ta), titanium nitride (TiN), tantalum nitride (TaN) or a combination thereof, but not limited thereto.

Next, a plurality of memory components 500 (see FIG. 3) are formed in the memory region 102. Herein, the memory components 500 are exemplary MTJ components. First, a contact etch stop layer (CESL) 330 may be optionally formed on the metal interconnect structure 300. Next, a metal interconnect process may be performed to form a metal interconnect structure 400 on the contact etch stop layer 330. The metal interconnect structure 400 includes an inter-metal dielectric layer 410 and contact structures 420 embedded in the inter-metal dielectric layer 410. The contact structure 420 passes through the contact etch stop layer 330 and is electrically connected with the aforementioned wire 320. The contact structure 420 may include, for example, a via conductor. Herein, the contact structure 420 is exemplary a multi-layer structure and includes a barrier layer 421 and a metal layer 422. A material of the barrier layer 421 may include titanium (Ti), tantalum (Ta), titanium nitride (TiN), tantalum nitride (TaN) or a combination thereof, and a material of the metal layer 422 may include aluminum (Al), titanium (Ti), tantalum (Ta), tungsten (W), niobium (Nb), molybdenum (Mo), copper (Cu) or a combination thereof, but not limited thereto. According to an embodiment of the present disclosure, the material of the barrier layer 421 includes titanium nitride, and the material of the metal layer 422 includes tungsten.

A material of the contact etch stop layer 330 may include a nitride, such as silicon nitride (SiN) or silicon nitricarbide (SiCN), but not limited thereto. A material of each of the inter-metal dielectric layers 310 and 410 may independently include silicon dioxide (SiO₂), tetraethoxysilane (TEOS), silicon nitride (SiN), silicon oxynitride (SiON), silicon nitride carbide (SiCN), nitrogen-doped silicon carbide (NDC), low dielectric constant (low-k) dielectric materials such as fluorinated silica glass (FSG), SiCOH, spin-on glass, ultra-low dielectric constant (ULK) dielectric material, organic polymer dielectric material, plasma-enhanced oxide, or other suitable dielectric materials. The aforementioned ULK dielectric material may include porous dielectric materials, such as silicon oxycarbide (SiOC), but not limited thereto. According to an embodiment of the present disclosure, the inter-metal dielectric layer 310 includes an ULK dielectric material, and the inter-metal dielectric layer 410 includes tetraethoxysilane, but not limited thereto.

Next, as shown in FIG. 2, a MTJ material stack (not shown) may be firstly formed on the metal interconnect structure 400. Forming the MTJ material stack may include sequentially forming a bottom electrode material layer (not shown), a MTJ main structure material layer (not shown) and a top electrode material layer (not shown). Next, semiconductor processes, such as photolithography and etching processes, are performed to remove a portion of the MTJ material stack to form a plurality of MTJ stacks 550, and then a shielding layer 540 is formed to cover the inter-metal dielectric layer 410 and the top surface and the side surfaces of each of the MTJ stacks 550. Each of the MTJ stacks 550 may include a bottom electrode layer 510, a MTJ main structure 520 and a top electrode layer 530 from bottom to top. In the process of removing the portion of the MTJ material stack, a portion of the inter-metal dielectric layer 410 is also removed. Therefore, a top surface 411 of the inter-metal dielectric layer 410 is recessed downwardly and is lower than a top surface 423 of each of the contact structures 420.

A material of each of the bottom electrode layer 510 and the top electrode layer 530 may independently include titanium (Ti), tantalum (Ta), titanium nitride (TiN), tantalum nitride (TaN) or a combination thereof. The MTJ main structure 520 may include a pinned layer (not shown), a resistance conversion layer (not shown) and a free layer (not shown) stacked in sequence. Each of the pinned layer and the free layer may independently include a ferromagnetic material, such as iron, cobalt, nickel or an alloy thereof, such as CoFe, NiFe or cobalt-iron-boron (CoFeB), and the material of the resistance conversion layer may include chromium (Cr), ruthenium (Ru), titanium nitride (TiN), tantalum nitride (TaN), aluminum (Al), magnesium (Mg) or magnesium oxide (MgO), but not limited thereto. The material of the shielding layer 540 may include a nitride, such as silicon nitride, but not limited thereto.

Next, as shown in FIG. 3, a dielectric layer 600 is formed to fully cover the shielding layer 540, and then the portions of the dielectric layer 600 and the shielding layer 540 located above the MTJ stacks 550 are removed to expose the top electrode layer 530 of each of the MTJ stacks 550, so that the memory components 500 are obtained. Moreover, the portions of the dielectric layer 600 and the shielding layer 540 located at two sides of the memory components 500 are removed to expose the portion of the contact etch stop layer 330 on which the memory components 500 are not disposed. The memory components 500 may be arranged along the horizontal direction D1, and may be arranged along another horizontal direction D3 to form an array (not shown).

A material of the dielectric layer 600 may include a low-k dielectric material, such as a dielectric material with a dielectric constant of 3.5 to 4.5. According to an embodiment of the present disclosure, the material of the dielectric layer 600 includes silicon oxide, and the dielectric layer 600 is formed by an atomic layer deposition (ALD) process. When a gap between any two adjacent ones of the memory components 500 is small, it is beneficial to fill the dielectric layer 600 into the gap between any two adjacent ones of the memory components 500 by the atomic layer deposition process.

Each of the memory components 500 includes the contact structure 420, the MTJ stack 550 and the shielding layer 540 disposed on the side surfaces of the MTJ stack 550. The relevant principles of the memory components 500 are well known in the art and are not described in detail herein. At this stage, the memory components 500 protrude from the surface of the semiconductor device (not labeled) shown in FIG. 3. For example, the memory components 500 protrude relative to the contact etch stop layer 330 in the vertical direction D2. The aforementioned vertical direction D2, for example, may be perpendicular to the top surface 101 of the substrate 100.

Next, as shown in FIG. 4, a dielectric layer 700 is formed to cover the memory components 500. A material of the dielectric layer 700 may include an ULK dielectric material, such as a dielectric material with a dielectric constant less than 4, and preferably a dielectric material with a dielectric constant of 2 to 3.5. The ULK dielectric material may include porous dielectric materials, such as silicon oxycarbide (SiOC), but not limited thereto. In other embodiment, the dielectric layer 600 may be omitted, and the dielectric layer 700 directly fills the gaps between the memory components 500 and covers the memory components 500. In this case, the portion of the shielding layer 540 on the top electrode layer 530 of each of the memory components 500 is reserved, and may be removed in subsequent process according to actual needs.

The dielectric layer 700 substantially follows the surface morphology of the memory components 500 and the dielectric layer 600, and thus includes a protruding portion 710 corresponding to the memory components 500. The dielectric layer 700 includes a non-protruding portion 720 disposed adjacent to the protruding portion 710. The protruding portion 710 is located on the memory components 500, and the non-protruding portion 720 is located on the region of the contact etch stop layer 330 without the memory components 500. The protruding portion 710 may have a protruding height H1 relative to the non-protruding portion 720. The protruding height H1 may be substantially identical to a height H2 of one of the memory components 500 in the vertical direction D2. For example, the following condition may be satisfied: 1600 Å≤H2≤1750 Å. The aforementioned protruding height H1 may be a height of the protruding portion 710 protruding relative to the non-protruding portion 720 in the vertical direction D2. The aforementioned protruding height H2 may be defined as a height difference between the top surface 501 of one of the memory components 500 and the film layer (herein, the contact etch stop layer 330) below the one of the memory components 500 in the vertical direction D2.

Since the dielectric layer 700 has the protruding portion 710, the dielectric layer 700 is required to be planarized. For example, at least the protruding portion 710 is required to be removed to facilitate the formation of other layers on the dielectric layer 700 in subsequent processes. However, it is difficult to planarize the dielectric layer 700 by the known planarization processes. Taking the etching process as an example, since the protruding portion 710 and the non-protruding portion 720 are made of the same material, the protruding portion 710 and the non-protruding portion 720 do not have etching selectivity. During the etching process, the heights of the protruding portion 710 and the non-protruding portion 720 are reduced by the same rate and the original surface morphology is remained. Taking the chemical mechanical polishing (CMP) process as another example, the protruding portion 710 is a bulk structure and has a larger polishing area. In practical, it is not easy to remove the protruding portion 710 by the CMP process. That is, the feasibility of directly removing the protruding portion 710 by the CMP process is low, or even if it is feasible, the polishing efficiency is extremely poor. In the present disclosure, the planarization of the dielectric layer 700 is achieved by improving the method for planarizing the surface of the semiconductor device, and the details are described as follows.

Please refer to FIGS. 5 to 7, a portion of the protruding portion 710 is etched to form a sidewall structure 730, which may include steps as follows. First, as shown in FIG. 5, a patterned mask 800 is formed to cover the dielectric layer 700, in which the patterned mask 800 includes an opening 810 corresponding to a portion of the protruding portion 710. For example, an edge of the opening 810 does not exceed the outer side of the outermost memory component 500 (such as the right side of the rightmost memory component 500 or the left side of the leftmost memory component 500), so that the portion of the protruding portion 710 is exposed from the opening 810. Next, an etching process may be performed to etch the portion of the protruding portion 710 exposed from the opening 810 to formed a recess 740. The aforementioned etching process may be, for example, a dry etching process, in which an etching gas P1 may be introduced to etch the portion of the protruding portion 710 exposed from the opening 810, so as to formed the recess 740 in the protruding portion 710, as shown in FIG. 6. The remaining portion of the protruding portion 710 located at two sides of the recess 740 forms the sidewall structure 730. The sidewall structure 730 is adjacent to the recess 740, and the sidewall structure 730 overlaps the outermost memory component 500 in the vertical direction D2. The sidewall structure 730 may include an etched side surface 731 and a non-etched side surface 732. The etched side surface 731 faces the recess 740. The non-etched side surface 732 is disposed opposite to the etched side surface 731. The aforementioned etching process only removes the dielectric layer 700 and does not remove the memory components 500 and the dielectric layer 600. That is, the recess 740 does not expose the memory components 500 and the dielectric layer 600 located below the dielectric layer 700. Afterward, the patterned mask 800 is removed.

In the present disclosure, the etching conditions may be controlled, such as adjusting compositions and the proportions of the compositions of the etching gas P1, so that a portion of the etching gas P1 reacts to form a protective layer 910 to cover a bottom of the etched side surface 731 of the sidewall structure 730 during the process of etching the protruding portion 710. Thereby, the etching degree of the bottom of the sidewall structure 730 is smaller than the etching degree of the top of the sidewall structure 730. Next, a cleaning process P2 may be performed to remove the protective layer 910.

According to an embodiment, the etching gas P1 may include tetrafluoromethane (CF₄), hexafluoroethane (C₂F₈) and oxygen (O₂). When a conventional etching gas includes the tetrafluoromethane, a portion of the tetrafluoromethane reacts to form a polymer during the etching process. The polymer may adhere to the etched side surface 731 of the sidewall structure 730 to reduce the etching efficiency. Therefore, the polymer is regarded as a by-product that is not beneficial to the etching process. In general, a reactive gas such as oxygen is introduced to react with the polymer to consume the polymer.

In the present disclosure, by adding the hexafluoroethane with a larger molecular weight than that of the tetrafluoromethane and reducing the introducing amount of the oxygen in the etching process, it is favorable for the polymer to be accumulated at the bottom of the sidewall structure 730 by increasing the molecular weight of the polymer. Moreover, the polymer can be prevented from being completely consumed by the oxygen, which is favorable for the polymer accumulated at the bottom of the sidewall structure 730 to form the protective layer 910, so that the etching degree of the bottom of the sidewall structure 730 is smaller than the etching degree of the top of the sidewall structure 730. Thereby, an included angle A1 between the etched side surface 731 and the etched top surface 711 of the protruding portion 710 is an obtuse angle. For example, the included angle A1 may be greater than or equal to 100 degrees and less than or equal to 140 degrees. Alternatively, the included angle A1 may be greater than or equal to 105 degrees and less than or equal to 125 degrees.

As shown in FIG. 7, the sidewall structure 730 may have a thickness W1, and the thickness W1 may range from 0.125 micrometers (μm) to 0.5 μm. The aforementioned thickness W1 may be a length of the sidewall structure 730 in the horizontal direction D1. In the embodiment, the thickness W1 of the sidewall structure 730 gradually increases from top to bottom in the vertical direction D2. The aforementioned range of the thickness W1 may refer to the range of the average value of all the thicknesses W1 of the sidewall structure 730 in the vertical direction D2. Since the include angle A1 between the etched side surface 731 and the etched top surface 711 of the protruding portion 710 is an obtuse angle, the etched side surface 731 according to the present disclosure is not a vertical surface. Compared with a sidewall structure with a vertical etched side surface, the etched side surface 731 according to the present disclosure is beneficial to allow the sidewall structure 730 to have a thicker thickness W1 at the bottom thereof, which is beneficial to improve the strength of the bottom of the sidewall structure 730. The aforementioned vertical etched side surface may be, for example, perpendicular to the top surface 101 of the substrate 100.

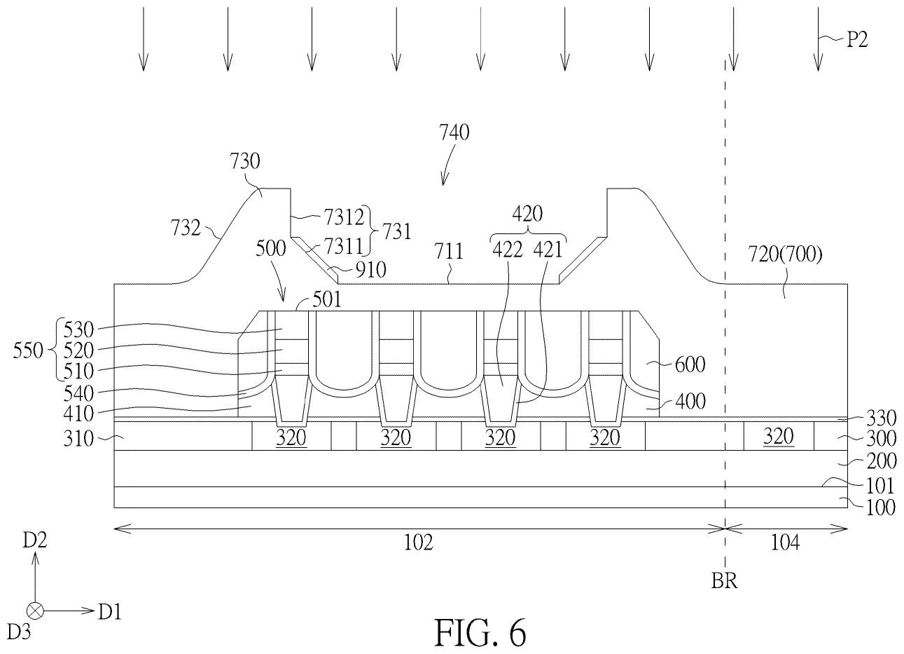

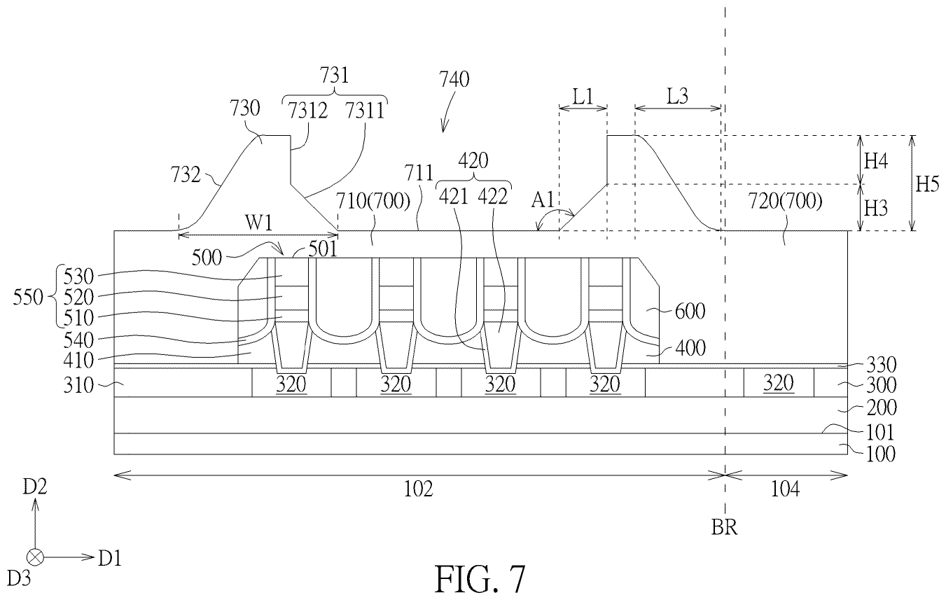

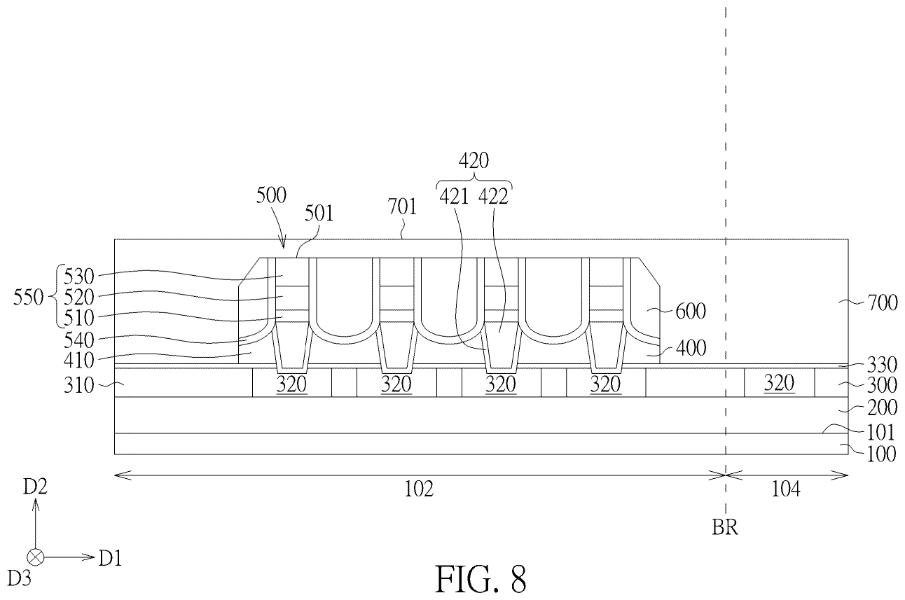

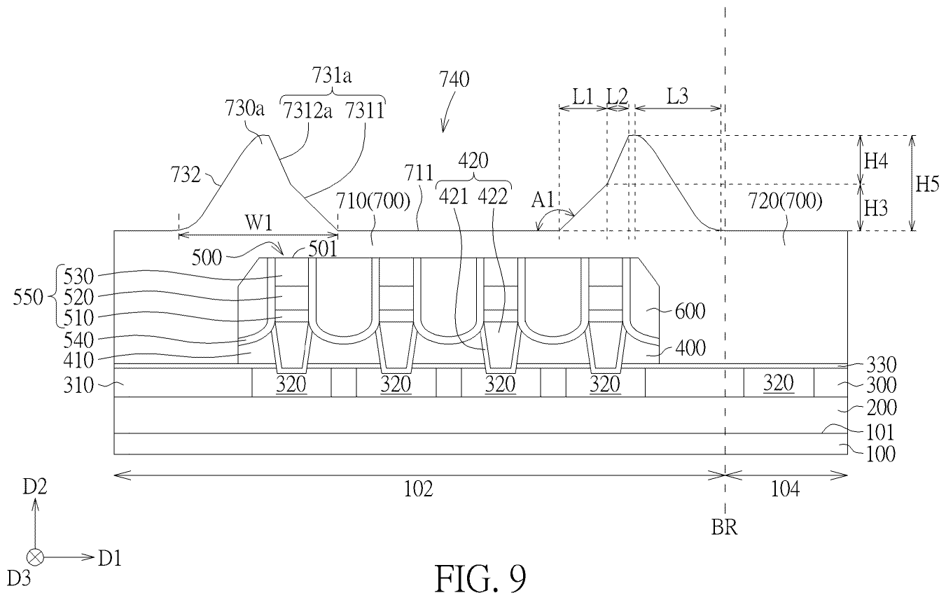

The etched side surface 731 may include a first portion 7311 and a second portion 7312 from bottom to top, and an inclined degree of the first portion 7311 is smaller than an inclined degree of the second portion 7312. In the embodiment, the second portion 7312 is a vertical surface, but not limited thereto. In other embodiments, the second portion 7312 may also be an inclined surface, which may refer to FIG. 9 and related description thereof. As shown in FIG. 7, the inclined degree of the first portion 7311 is equal to a height H3 of the first portion 7311 in the vertical direction D2 divided by a length L1 of the first portion 7311 in the horizontal direction D1 (the inclined degree is equal to H3/L1). The inclined degree of the second portion 7312 is equal to a height H4 of the second portion 7312 in the vertical direction D2 divided by a length of the second portion 7312 in the horizontal direction D1 (herein, the length is 0, the inclined degree is equal to H4/0, and H4/0 is equal to infinity).

An inclined degree of the non-etched side surface 732 may be smaller than an inclined degree of the etched side surface 731. The inclined degree of the etched side surface 731 is equal to the height of the etched side surface 731 in the vertical direction D2 (i.e., the total height (H3+H4) of the first portion 7311 and the second portion 7312 in the vertical direction D2) divided by the length L1 of the etched side surface 731 in the horizontal direction D1 (the inclined degree is equal to (H3+H4)/L1), the inclined degree of the non-etched side surface 732 is equal to the height H5 of the non-etched side surface 732 in the vertical direction D2 divided by the length L3 of the non-etched side surface 732 in the horizontal direction D1 (the inclined degree is equal to H5/L3). In the embodiment, the total height (H3+H4) of the first portion 7311 and the second portion 7312 in the vertical direction D2 is equal to the height H5 of the non-etched side surface 732 in the vertical direction D2, but not limited thereto. According to the above description, in the present disclosure, an inclined degree of a surface (such as the first portion 7311 of the etched side surface 731, the second portion 7312 of the etched side surface 731 or the non-etched side surface 732) may refer to a height of the surface in the vertical direction D2 divided by a length of the surface in the horizontal direction D1.

Next, as shown in FIG. 8, the sidewall structure 730 is removed to planarize the dielectric layer 700, but the memory components 500 and the dielectric layer 600 below the dielectric layer 700 are not exposed. In other words, by controlling the polishing time, only a portion of the dielectric layer 700 is removed. For example, the sidewall structure 730 is removed and the dielectric layer 700 located above the dielectric layer 700 is thinned, so that a flat top surface 701 can be obtained. According to an embodiment of the present disclosure, the sidewall structure 730 is removed by a CMP process. Afterward, other layers may be formed on the dielectric layer 700 according to design requirement.

According to the above description, it can be seen that when the included angle A1 between the etched side surface 731 of the sidewall structure (not shown) and the etched top surface 711 of the protruding portion 710 is a right angle or an acute angle, such sidewall structure has a thinner thickness at the bottom thereof. Therefore, when a planarization process such as a CMP process is performed to remove such sidewall structure, such sidewall structure is often broken by the polishing external force before the sidewall structure being polished to become flat, and a portion of the dielectric layer 700 connected with the sidewall structure is often broken along with the sidewall structure, which tends to generate dents and/or scratches on the top surface 701 of the dielectric layer 700. The yield of subsequent processes tends to be affected by the dents and/or scratches. For example, when a metal interconnection process is performed on the dielectric layer 700, the metal materials fill in the dents and/or scratches may generate bridges between different metal wires and cause short circuits. Accordingly, the properties and/or yield of the semiconductor devices formed later are affected.

In the present disclosure, by removing a portion of the dielectric layer 700 to form the sidewall structure 730, and by controlling the etching conditions, the included angle A1 between the etched side surface 731 and the etched top surface 711 of the protruding portion 710 is allowed to be an obtuse angle, so that the bottom of the sidewall structure 730 is configured with a thicker thickness W1. Afterward, a planarization process such as a CMP process is performed to planarize the dielectric layer 700. On the one hand, the polishing area can be reduced by forming the sidewall structure 730, which allows the CMP to be feasible, and is beneficial to enhance the polishing efficiency. On the other hand, the sidewall structure 730 has a thicker thickness W1 at the bottom, which can provide the strength to support the sidewall structure 730. Therefore, the sidewall structure 730 can be planarized gradually, and the break of the sidewall structure 730 during the planarization process to damage the top surface 701 of the dielectric layer 700 can be prevented.

The aforementioned film layers, such as the inter-metal dielectric layers 310 and 410, the contact etch stop layer 330, the dielectric layers 600 and 700, etc., may be formed by any suitable methods. For example, the methods may be, but are not limited to, molecular-beam epitaxy (MBE), physical vapor deposition (PVD), chemical vapor deposition (CVD), such as metal organic chemical vapor deposition (MOCVD), sub-atmospheric chemical vapor deposition (SACVD) and plasma-enhanced chemical vapor deposition (PECVD), hydride vapor phase epitaxy (HVPE) and atomic layer deposition (ALD).

Please refer to FIG. 9, which is a schematic cross-sectional view showing a step of a method for planarizing a surface of a semiconductor device according to another embodiment of the present disclosure. The step shown in FIG. 9 corresponds to the step shown in FIG. 7. The difference between FIG. 9 and FIG. 7 is that the structure of the etched side surface 731a of the sidewall structure 730a is different from the structure of the etched side surface 731 of the sidewall structure 730, in which the second portion 7312a of the etched side surface 731a is not a vertical surface.

Specifically, the etched side surface 731a may include a first portion 7311 and a second portion 7312a from bottom to top. An inclined degree of the first portion 7311 is smaller than an inclined degree of the second portion 7312a. In the embodiment, the second portion 7312a is an inclined surface. The inclined degree of the second portion 7312a is equal to the height H4 of the second portion 7312a in the vertical direction D2 divided by the length L2 of the second portion 7312a in the horizontal direction D1. For example, the etching conditions may be controlled, such as adjusting compositions and the proportions of the compositions of the etching gas P1 (refer to FIG. 5), so as to control the rate that the etching gas P1 forms the protective layer 910 (refer to FIG. 6) and to control the range that the protective layer 910 covers the bottom of the sidewall structure 730a, and the second portion 7312a with a different inclined degree can be obtained. For other details about the method of planarizing the surface of the semiconductor device shown in FIG. 9, reference may be made to the relevant description above and is not repeated herein.

Compared with the prior art, in the method for planarizing a surface of a semiconductor device according the present disclosure, by controlling the etching conditions to allow the included angle between the etched side surface and the etched top surface of the protruding portion to be an obtuse angle, the strength of the bottom of the sidewall structure can be improved. Therefore, the break of the sidewall structure caused by the polishing external force before being polished to become flat can be prevented. It is beneficial to reduce the probability of damaging the surface of the semiconductor device desired to be planarized during the polishing process, so as to improve the properties and/or yield of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for planarizing a surface of a semiconductor device, comprising:
providing a substrate defining a memory region, wherein a memory component is disposed on the substrate and located in the memory region;
forming a dielectric layer to cover the memory component, wherein the dielectric layer comprises a protruding portion corresponding to the memory component;
etching a portion of the protruding portion to form a sidewall structure, wherein the sidewall structure comprises an etched side surface, and an included angle between the etched side surface of the sidewall structure and an etched top surface of the protruding portion is an obtuse angle; and
removing the sidewall structure to planarize the dielectric layer.

2. The method of claim 1, wherein the included angle is greater than or equal to 100 degrees and less than or equal to 140 degrees.

3. The method of claim 1, wherein the etched side surface comprises a first portion and a second portion from bottom to top, and an inclined degree of the first portion is smaller than an inclined degree of the second portion.

4. The method of claim 1, wherein the sidewall structure further comprises a non-etched side surface disposed opposite to the etched side surface, and an inclined degree of the non-etched side surface is smaller than an inclined degree of the etched side surface.

5. The method of claim 1, wherein etching the portion of the protruding portion comprises forming a recess, the sidewall structure is adjacent to the recess, and the etched side surface faces the recess.

6. The method of claim 5, wherein etching the portion of the protruding portion comprises:
forming a patterned mask to cover the dielectric layer, wherein the patterned mask comprises an opening corresponding to the portion of the protruding portion; and
etching the portion of the protruding portion to form the recess.

7. The method of claim 1, wherein the portion of the protruding portion is etched by a dry etching process.

8. The method of claim 7, wherein etching the portion of the protruding portion comprises:
introducing an etching gas, wherein a portion of the etching gas reacts to form a protective layer covering a bottom of the etched side surface; and
removing the protective layer.

9. The method of claim 1, wherein removing the sidewall structure to planarize the dielectric layer is by a chemical mechanical polishing process.

10. The method of claim 1, wherein the dielectric layer comprises an ultra-low dielectric constant dielectric material.

11. The method of claim 1, wherein the memory component is a magnetic tunnel junction component.
